(19) United States
(12) Patent Application Publication
(10) Pub. No.: US 2017/0077279 A1
(43) Pub. Date: Mar. 16, 2017

(54) SEMICONDUCTOR DEVICE

(71) Applicant: KABUSHIKI KAISHA TOSHIBA, Tokyo (JP)

(72) Inventor: Takashi ONIZAWA, Nomi Ishikawa (JP)

(21) Appl. No.: 15/061,973

(22) Filed: Mar. 4, 2016

(30) Foreign Application Priority Data
Sep. 11, 2015 (JP) 2015-179129

(51) Int. Cl. H01L 29/778; H01L 29/868; H01L 29/10; H01L 29/20; H01L 29/417; H01L 23/535

(52) U.S. Cl. CPC H01L 29/7787; H01L 29/41775; H01L 23/535; H01L 29/1054; H01L 29/2003; H01L 29/868

(57) ABSTRACT

A semiconductor device includes a semiconductor substrate which includes a first surface, a second surface, and an end portion, the semiconductor substrate including a first region of a p-type and a second region of an n-type provided in a corner portion of the semiconductor substrate between the first surface and the end surface, a nitride semiconductor layer on the first surface, and an electrode on the nitride semiconductor layer.

### CROSS-REFERENCE TO RELATED APPLICATION

This application is based upon and claims the benefit of priority from Japanese Patent Application No. 2015-179129; filed Sep. 11, 2015, the entire contents of which are incorporated herein by reference.

### FIELD

Embodiments described herein relate generally to a semiconductor device.

### BACKGROUND

A plurality of semiconductor elements formed in a semiconductor wafer are divided into a plurality of semiconductor chips by dicing the semiconductor wafer along dicing regions provided in the semiconductor wafer. In some cases, a leakage current may flow through an edge portion of the semiconductor chip formed by the dicing, and the leakage current may cause a breakdown of the semiconductor chip.

### DESCRIPTION OF THE DRAWINGS

FIGS. 1A and 1B are schematic views illustrating a semiconductor device according to a first embodiment.

FIGS. 2-10 are each a cross-sectional view illustrating a fabrication method of the semiconductor device according to the first embodiment.

FIGS. 11A and 11B are respectively a schematic view and a circuit diagram illustrating a semiconductor device according to a second embodiment.

### DETAILED DESCRIPTION

Embodiments provide a semiconductor device which prevents a leakage current from flowing through an edge portion of a semiconductor chip.

In general, according to one embodiment, a semiconductor device includes a semiconductor substrate that includes a first surface, a second surface, and an end face, the semiconductor substrate including a first region of a p-type and a second region of an n-type provided in a corner portion of the semiconductor substrate between the first surface and the end face, a nitride semiconductor layer on the first surface, and an electrode on the nitride semiconductor layer.

Embodiments of the invention will be hereinafter descried with reference to the drawings. In the following description, the same symbols or reference numerals will be given to the same or similar elements, and description of the elements described once will be repeated only as needed.

In addition, in the specification, a “GaN-based semiconductor” is a general term for a semiconductor that contains gallium nitride (GaN), aluminum nitride (AlN), indium nitride (InN), and an intermediate composition of the foregoing.

### First Embodiment

A semiconductor device according to the present embodiment includes a semiconductor substrate mainly of a p-type that includes a first surface, a second surface, an end face, and an n region provided in a corner portion between the first surface and the end face, a nitride semiconductor layer that is provided on the first surface, and an electrode that is provided on the nitride semiconductor layer.

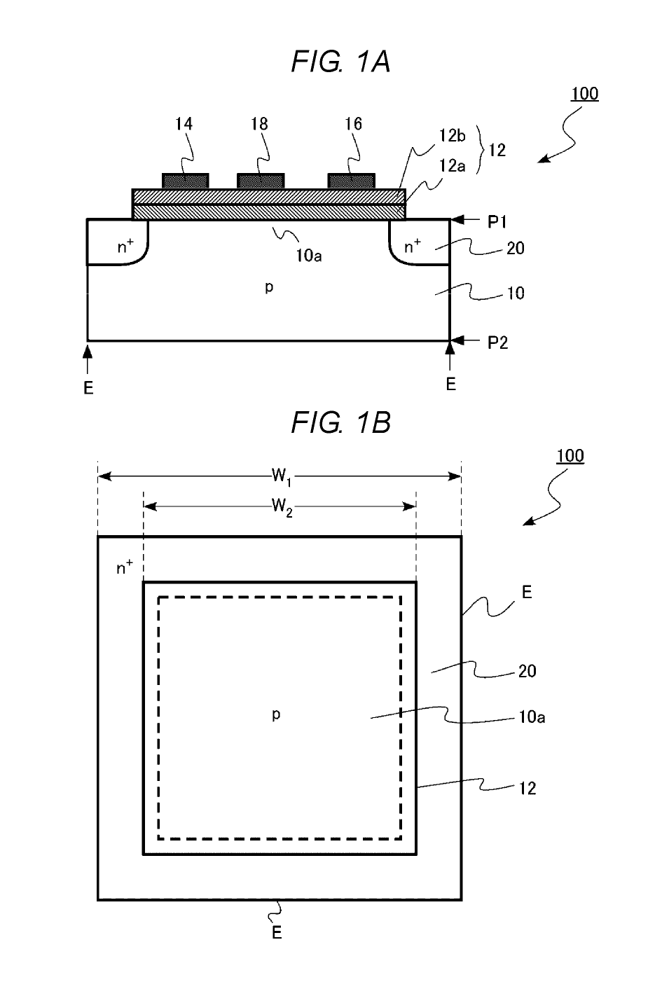

FIGS. 1A and 1B are schematic views illustrating a semiconductor device according to the present embodiment. FIG. 1A is a sectional view of the semiconductor device, and FIG. 1B is a top view of the semiconductor device.

The semiconductor device according to the present embodiment is a semiconductor chip 100. The semiconductor chip 100 includes a silicon substrate 10, a GaN-based semiconductor layer (nitride semiconductor layer) 12, a source electrode 14, a drain electrode 16, and a gate electrode 18. The silicon substrate 10 includes a p-type region 10a and an n-type region 20. The GaN-based semiconductor layer 12 includes a first GaN-based semiconductor film. 12a and a second GaN-based semiconductor film 12b.

A semiconductor element is formed in the semiconductor chip 100. The semiconductor element is, for example, a high electron mobility transistor (HEMI).

The silicon substrate 10 includes a first surface P1, a second surface P2, and an end face E. The p-type region 10a contains p-type impurity. The p-type impurity is, for example, boron B. The p-type impurity concentration of the p-type region 10a is, for example, higher than or equal to 1×10¹⁴ cm⁻³ and lower than or equal to 5×10¹⁸ cm⁻³. In addition, the p-type impurity concentration of the p-type region 10a is, for example, higher than or equal to 1×10¹⁴ cm⁻³ and lower than or equal to 5×10¹⁵ cm⁻³.

The silicon substrate 10 includes the n-type region 20 in a corner portion between the first surface P1 and the end face E. The n-type region 20 contains n-type impurity. The n-type impurity is, for example, phosphorus (P) or arsenic (As). The n-type impurity concentration of the n-type region 20 is higher than the p-type impurity concentration of the p-type region 10a. The n-type impurity concentration of the n-type region 20 is, for example, higher than or equal to 1×10¹⁸ cm⁻³ and lower than or equal to 1×10²¹ cm⁻³.

The p-type impurity concentration of the p-type region 10a, and the n-type impurity concentration of the n-type region 20 can be measured by a secondary ion mass spectrometry (SIMS).

The n-type region 20 is formed in the silicon substrate 10, and thereby a PIN diode is formed in the silicon substrate 10. The p-type region 10a serves as an anode electrode of the PIN diode, and the n-type region 20 serves as a cathode electrode of the PIN diode.

As illustrated in FIG. 1B, the n-type region 20 is provided to surround the p-type region 10a, in the first surface P1. The p-type region 10a is a part of the silicon substrate 10, and a part thereof becomes a region with p-type conductivity in contact with the first surface.

Bonding between the n-type region 20 and the p-type region 10a is terminated at the end face E of the silicon substrate 10.

The GaN-based semiconductor layer 12 has a stacking structure in which the second GaN-based semiconductor film 12b is stacked on the first GaN-based semiconductor film. 12a. The second GaN-based semiconductor film 12b is provided on the first GaN-based semiconductor film 12a. The bandgap energy of the second GaN-based semiconductor film. 12b is greater than the bandgap energy of the first GaN-based semiconductor film 12a.

The first GaN-based semiconductor film 12a is, for example, a gallium nitride (GaN) film. The second GaN-based semiconductor film 12b is, for example, aluminum gallium nitride (AlGaN).

The source electrode 14 of an HEMT, the drain electrode 16, and the gate electrode 18 are provided on a surface of the second GaN-based semiconductor film 12b. The source electrode 14, the drain electrode 16, and the gate electrode 18 are, for example, metals.

For example, a protection film which is not illustrated is provided on the source electrode 14, the drain electrode 16, and the gate electrode 18. The protection film is, for example, a silicon oxide film. It does not matter if a gate insulating film (not shown) is provided between the second GaN-based semiconductor film 12b and the gate electrode 18.

A width (W₁ of FIG. 1B) of the silicon substrate 10 is greater than a width (W₂ of FIG. 1B) of the GaN-based semiconductor layer 12. In other words, a part of the silicon substrate 10 protrudes outwardly with respect to the GaN-based semiconductor layer 12, in an end portion of the semiconductor chip 100.

A part of the GaN-based semiconductor layer 12 is provided on the n-type region 20. An end portion of the GaN-based semiconductor layer 12 is provided on the n-type region 20. In other words, the end portion of the GaN-based semiconductor layer 12 and the n-type region 20 overlap each other on the first surface P1.

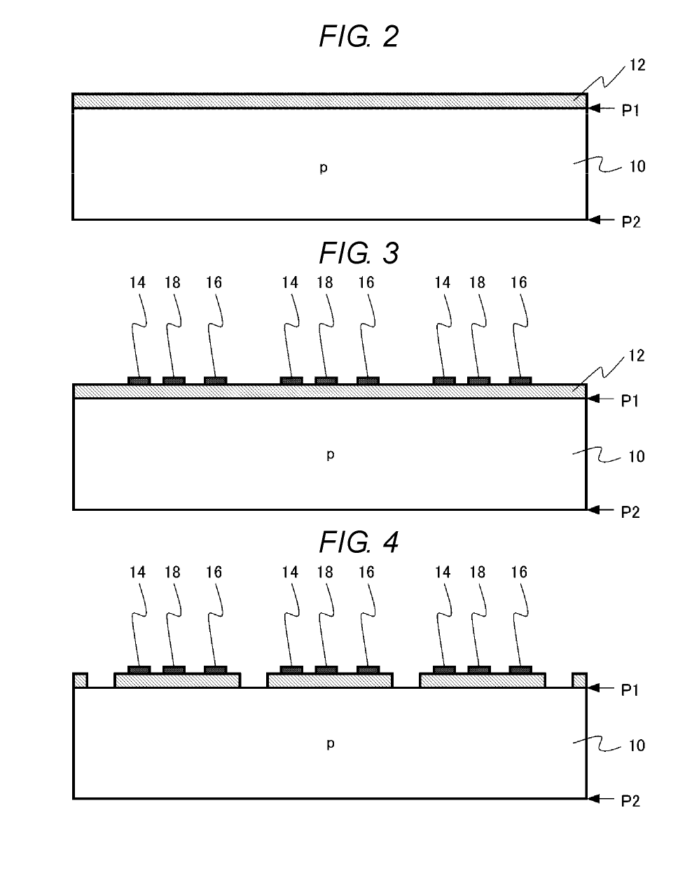

FIG. 2 to FIG. 10 are schematic sectional views each illustrating a step in the fabrication method of the semiconductor device according to the present embodiment.

First, a semiconductor wafer in which the GaN-based semiconductor layer 12 is provided on the silicon substrate 10 (which is initially entirely of p-type) is prepared (FIG. 2). The silicon substrate 10 includes the first surface P1 and the second surface P2.

A thickness of the silicon substrate 10 is, for example, greater than or equal to 1 mm and smaller than or equal to 2 mm. A thickness of the GaN-based semiconductor layer 12 is, for example, greater than or equal to 5 μm and smaller than or equal to 10 μm.

The GaN-based semiconductor layer 12 is provided on the first surface P1 of the silicon substrate 10. The GaN-based semiconductor layer 12 is formed on the silicon substrate 10 using an epitaxial growth method. The GaN-based semiconductor layer 12 includes, for example, a stacking structure of a GaN film and an AlGaN film. Two-dimensional electron gas (2DEG) which is formed on a boundary between the GaN film and the AlGaN film becomes a carrier of the HEMT.

Subsequently, a plurality of semiconductor elements are formed on the GaN-based semiconductor layer 12. The semiconductor elements are each an HEMT. For example, the source electrode 14 of the HEMT, the drain electrode 16, and the gate electrode 18 are formed on the surface of the GaN-based semiconductor layer 12 (FIG. 3). A protection film which is not illustrated is formed on the source electrode 14, the drain electrode 16, and the gate electrode 18. The protection film is, for example, a silicon oxide film.

Subsequently, portions of the GaN-based semiconductor layer 12 in a dicing region are selectively etched until the silicon substrate 10 is exposed (FIG. 4). The dicing region is a region with a predetermined width at which the plurality of semiconductor elements are diced into a plurality of semiconductor chips. The dicing region is provided on the surface side of the GaN-based semiconductor layer 12. A pattern of the semiconductor element is not formed in the dicing region. For example, the dicing region is provided in a lattice shape on the surface side of the GaN-based semiconductor layer 12, such that the semiconductor elements can be partitioned thereby.

Etching of the GaN-based semiconductor layer 12 is performed by, for example, reactive ion etching (RIE). The etching of the GaN-based semiconductor layer 12 is performed by using, for example, a resist which is not illustrated, as a mask. The etching of the GaN-based semiconductor layer 12 may be performed by other etching, such as dry etching or wet etching.

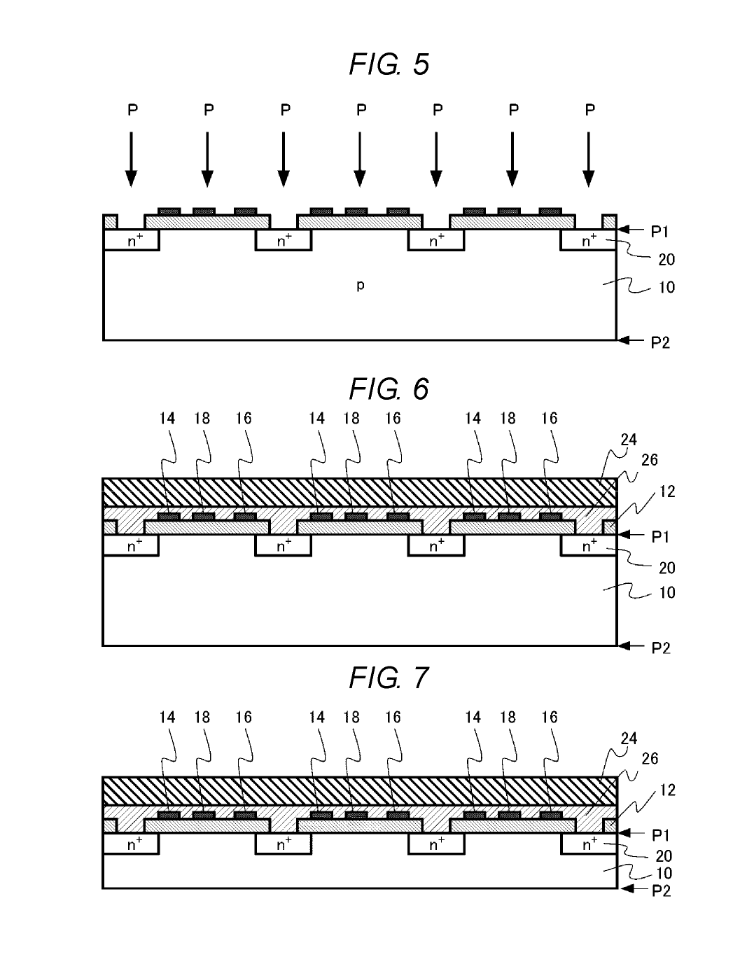

Subsequently, n-type impurity is injected into the silicon substrate 10 which is exposed in the dicing region using an ion injection method (FIG. 5). The n-type region 20 is formed by injecting n-type impurity using an ion injection method. The n-type impurity is, for example, phosphorus (P). The n-type impurity may also be arsenic (As). The n-type impurity can be activated by, for example, laser annealing.

Subsequently, a supporting member 24 is bonded on the GaN-based semiconductor layer 12 (FIG. 6). The supporting member 24 adheres to the GaN-based semiconductor layer 12 using, for example, an adhesion layer 26.

The supporting member 24 has a function of reinforcing the semiconductor wafer, when the wafer is ground to be thinned. The supporting member 24 is, for example, a glass substrate.

Subsequently, the silicon substrate 10 is ground to be thinned from the second surface P2 side of the silicon substrate 10 (FIG. 7). The silicon substrate 10 is thinned to have a thickness, for example, greater than or equal to 100 μm and smaller than or equal to 200 μm.

The thinning of the silicon substrate 10 is performed by so-called back grinding. The thinning of the silicon substrate 10 is performed by grinding using, for example, a diamond wheel.

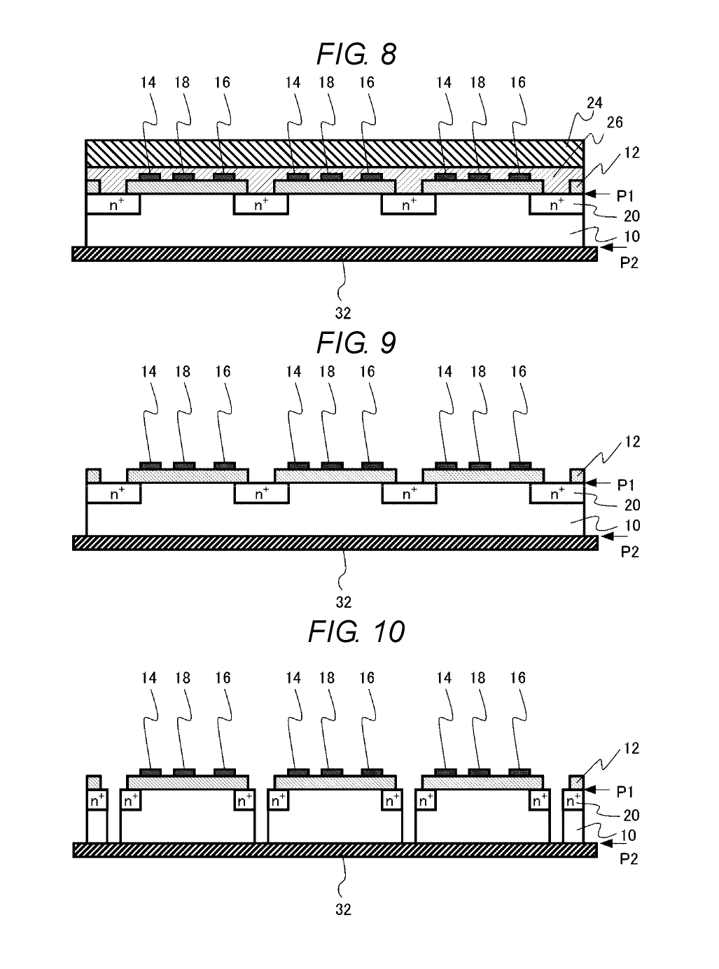

Subsequently, a resin sheet 32 is attached to the second surface P2 side of the silicon substrate 10 (FIG. 8). The resin sheet 32 is, for example, a dicing tape. In one embodiment, the resin sheet 32 is fixed to a metal frame for improved handling.

Subsequently, the supporting member 24 is peeled from the semiconductor wafer (FIG. 9).

Subsequently, regions of the silicon substrate 10 between the GaN-based semiconductor layers 12 are cut by dicing with a blade from the first surface P1 side (FIG. 10). The silicon substrate 10 is cut along the dicing regions.

Thereafter, the resin sheet 32 is peeled from the silicon substrate 10, and thereby a plurality of semiconductor chips (semiconductor devices) 100 which have been divided as a result of dicing are obtained.

By the aforementioned fabrication method, the semiconductor chip 100 according to the present embodiment illustrated in FIG. 1 is easily fabricated.

Thereafter, each semiconductor chip 100 is mounted in a semiconductor package. For example, the semiconductor chip 100 is attached on a lead frame and sealed with a molding resin.

Hereinafter, actions and effects of the semiconductor device according to the present embodiment will be described.

It should be recognized that a leakage current flowing through an end portion of the semiconductor chip may cause the semiconductor chip to breakdown. The breakdown of the semiconductor chip is made by, for example, a short circuit of an electrode formed on an upper surface of the semiconductor chip and the semiconductor substrate.

In the HEMT according to the present embodiment, a leakage current flows between, for example, the drain electrode 16 to which a high positive voltage is applied, and, for example, the silicon substrate 10 which is fixed to a ground potential. In such a case, heat is generated and a breakdown of an insulating film is possible.

The leakage current flows into a surface of the end portion of the semiconductor chip 100 through moisture or conductive particles existing on a surface of the end portion of the GaN-based semiconductor layer 12 or the end face E of the silicon substrate 10. Alternatively, the leakage current flows into the end portion of the semiconductor chip 100 through a cracked portion which is formed in the end portion of the GaN-based semiconductor layer 12 at the time of dicing. Since a GaN-based semiconductor is harder and more brittle than silicon, the GaN-based semiconductor may crack more easily than silicon at the time of dicing. In addition, the GaN-based semiconductor formed on the silicon substrate may easily crack as a result of stress being produced therebetween.

In the present embodiment, the n-type region 20 is formed on the corner portion of the silicon substrate 10, and thereby the PIN diode is provided. As a result, even if a high positive voltage applied to the drain electrode 16 is applied to the corner portion of the end portion of the silicon substrate 10 through the end portion of the GaN-based semiconductor layer 12, the PIN diode is reversely biased.

Hence, it is possible to prevent a leakage current from flowing between the drain electrode 16 and the silicon substrate 10. Thus, the breakdown of the semiconductor chip 100 is prevented.

In addition, it is preferable that the end portion of the GaN-based semiconductor layer 12 and the n-type region 20 overlap each other on the first surface P1. Since the end portion of the GaN-based semiconductor layer 12 and the n-type region 20 overlap each other, it is possible to effectively prevent a leakage current from flowing through a cracked portion which is formed in the end portion of the GaN-based semiconductor layer 12.

In addition, in the present embodiment, the GaN-based semiconductor layer 12 comes into direct contact with the p-type region 10a. For example, if the p-type region 10a is fixed to the ground potential, a diode formed in a substrate portion behaves as a protection element and a breakdown voltage of the HEMT which is formed in the GaN-based semiconductor layer 12 increases, by the GaN-based semiconductor layer 12 and the p-type region 10a which are in contact.

As such, according to the semiconductor chip 100 according to the present embodiment, it is possible to prevent a leakage current from flowing through the end portion of the semiconductor chip 100. Thus, the breakdown of the semiconductor chip 100 is prevented, and the semiconductor chip 100 with increased reliability is realized.

### Second Embodiment

A semiconductor device according to the present embodiment is different from the semiconductor device according to the first embodiment in that the semiconductor device according to the present embodiment further includes a first wire which electrically connects a source electrode to the p-type region 10a, and a second wire which electrically connects a drain electrode to the n-type region. Description of the content which overlaps that of the first embodiment will be omitted.

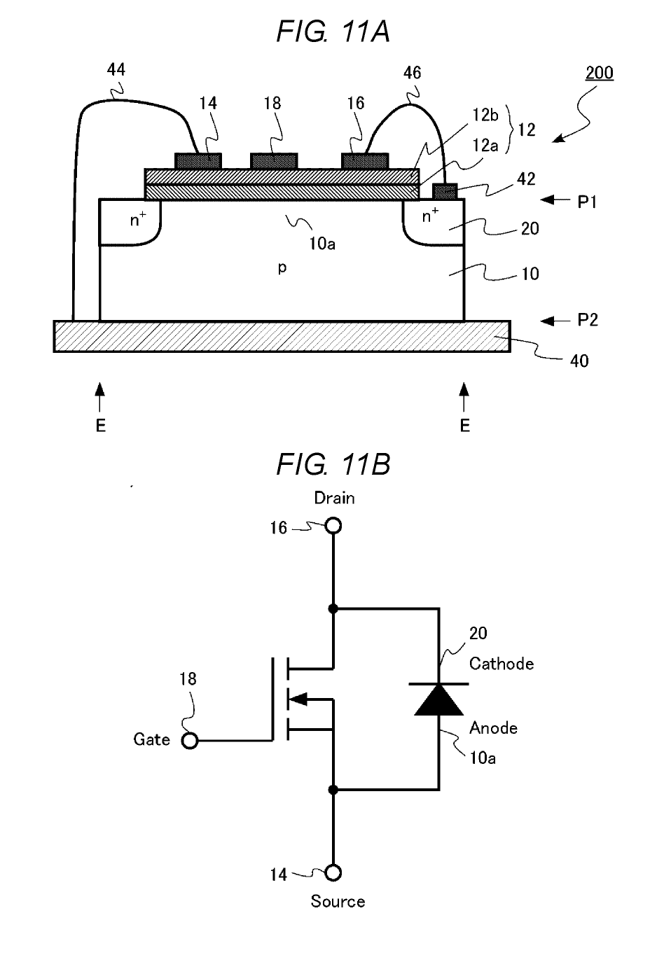

FIGS. 11A and 11B are a schematic view and a schematic diagram illustrating a semiconductor device according to the present embodiment. FIG. 11A is a sectional view of the semiconductor device, and FIG. 11B is an equivalent circuit of the semiconductor device.

The semiconductor device according to the present embodiment is a semiconductor package 200 in which a semiconductor chip is embedded. The semiconductor package 200 includes the silicon substrate 10, the GaN-based semiconductor layer (nitride semiconductor layer) 12, the source electrode 14, the drain electrode 16, the gate electrode 18, a lead frame (metal layer) 40, a metal electrode 42, a first wire 44, and a second wire 46. The silicon substrate 10 includes the p-type region 10a and the n-type region 20. The GaN-based semiconductor layer 12 includes the first GaN-based semiconductor film 12a, and the second GaN-based semiconductor film 12b.

A semiconductor element is formed in the semiconductor chip in the semiconductor package 200. The semiconductor element is, for example, an HEMT. The semiconductor chip is sealed with, for example, a molding resin which is not illustrated.

The silicon substrate 10 adheres to the lead frame 40 of a metal by using an adhesion layer which is not illustrated. The adhesion layer is, for example, a solder or a conductive paste.

The metal electrode 42 is provided on the n-type region 20. It is preferable that the metal electrode 42 comes into Ohmic contact with the n-type region 20.

The first wire 44 connects the source electrode 14 to the lead frame 40. The first wire 44 is, for example, a bonding wire of gold. The source electrode 14 and the silicon substrate 10 are electrically connected to each other by the first wire 44.

The second wire 46 connects the drain electrode 16 to the metal electrode 42. The second wire 46 is, for example, a bonding wire of gold. The drain electrode 16 and the n-type region 20 are electrically connected to each other by the second wire 46.

In the semiconductor package 200, an HEMT is connected in parallel with a PIN diode, as illustrated in FIG. 11B. The anode electrode 10a of the PIN diode is connected to the source electrode 14 of the HEMT. The cathode electrode 20 of the PIN diode is connected to the drain electrode 16 of the HEMT.

For example, if a large surge current flows into the drain electrode 16 of the HEMT, a gate insulating film or the like may break down. According to the semiconductor module 200 according to the present embodiment, even if a large surge current flows into the drain electrode 16, it is possible to make the current escape into the source electrode 14 through the PIN diode by appropriately setting a breakdown voltage of the PIN diode. Thus, the breakdown of the semiconductor package 200 can be prevented.

According to the semiconductor package 200 according to the present embodiment, a leakage current does not flow through the end portion of the semiconductor package 200 as in the first embodiment. Thus, the breakdown of the semiconductor package 200 is further prevented, and the semiconductor package 200 with increased reliability is realized.

Furthermore, by providing a configuration in which the HEMT is connected in parallel with the PIN diode, the breakdown of the semiconductor package 200 due to a surge current is prevented. Thus, it is possible to realize the semiconductor package 200 in which reliability is more increased.

In the first and second embodiments, an example in which a semiconductor element is an HEMT is used, but the semiconductor element is not limited to the HEMT. Other semiconductor elements such as a horizontal diode can also be applied.

In addition, in the first and second embodiments, an example in which a silicon substrate is used for the substrate is used, but a semiconductor substrate other than a silicon substrate, for example, other substrates such as a silicon carbide (SiC) substrate can be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate that includes a first surface, a second surface, and an end face, the semiconductor substrate including a first region of a p-type and a second region of an n-type provided in a corner portion of the semiconductor substrate between the first surface and the end face;
a nitride semiconductor layer on the first surface; and
an electrode on the nitride semiconductor layer.

2. The device according to claim 1, wherein a width of the semiconductor substrate is greater than a width of the nitride semiconductor layer.

3. The device according to claim 1, further comprising:
two additional electrodes on the nitride semiconductor layer, wherein
the three electrodes include a source electrode, a drain electrode, and a gate electrode between the source and drain electrodes.

4. The device according to claim 3, further comprising:
a first wire that electrically connects the source electrode to the first region; and
a second wire that electrically connects the drain electrode to the second region.

5. The device according to claim 3, wherein
the nitride semiconductor layer includes a first GaN-based semiconductor film, and a second GaN-based semiconductor film on the first GaN-based semiconductor film, the second GaN-based semiconductor film having a bandgap energy that is greater than a bandgap energy of the first GaN-based semiconductor film.

6. The device according to claim 1, wherein a concentration of n-type impurities in the second region is higher than a concentration of p-type impurities in the first region.

7. The device according to claim 6, wherein the concentration of the p-type impurities is higher than or equal to 1×10¹⁴ cm⁻³ and lower than or equal to 5×10¹⁵ cm⁻³.

8. The device according to claim 6, wherein the concentration of the n-type impurities is higher than or equal to 1×10¹⁸ cm⁻³ and lower than or equal to 1×10²¹ cm⁻³.

9. The device according to claim 1, wherein a part of the nitride semiconductor layer is in direct contact with the second region.

10. The device according to claim 1, wherein the semiconductor substrate is a silicon substrate.

11. A semiconductor device comprising:
a semiconductor substrate including a first region of a p-type and a second region of an n-type provided in an upper corner portion of the semiconductor substrate, the first region being surrounded by the second region on an upper surface of the semiconductor substrate;
a nitride semiconductor layer on the upper surface; and
source, gate, and drain electrodes on the nitride semiconductor layer.

12. The device according to claim 11, wherein a width of the semiconductor substrate is greater than a width of the nitride semiconductor layer.

13. The device according to claim 11, wherein the gate electrode is between the source and drain electrodes.

14. The device according to claim 13, further comprising:
a first wire that electrically connects the source electrode to the first region; and
a second wire that electrically connects the drain electrode to the second region.

15. The device according to claim 13, wherein
the nitride semiconductor layer includes a first GaN-based semiconductor film, and a second GaN-based semiconductor film on the first GaN-based semiconductor film, the second GaN-based semiconductor film having a bandgap energy that is greater than a bandgap energy of the first GaN-based semiconductor film.

16. The device according to claim 11, wherein a concentration of n-type impurities in the second region is higher than a concentration of p-type impurities in the first region.

17. The device according to claim 16, wherein the concentration of the p-type impurities is higher than or equal to 1×10¹⁴ cm⁻³ and lower than or equal to 5×10¹⁵ cm⁻³.

18. The device according to claim 16, wherein the concentration of the n-type impurities is higher than or equal to 1×10¹⁸ cm⁻³ and lower than or equal to 1×10²¹ cm⁻³.

19. The device according to claim 11, wherein a part of the nitride semiconductor layer is in direct contact with the second region.

20. The device according to claim 11, wherein the semiconductor substrate is a silicon substrate.
